(19) United States
(12) Patent Application Publication
(10) Pub. No.: US 2025/0046579 A1
(43) Pub. Date: Feb. 6, 2025

(54) COPPER-LAYER ETCHING METHOD AND SUBSTRATE PROCESSING APPARATUS

(71) Applicant: Tokyo Electron Limited, Tokyo (JP)

(72) Inventors: Hirotoshi SAKAUE, Nirasaki City (JP); Hitoshi SAITO, Nirasaki City (JP); Hajime UGAJIN, Nirasaki City (JP)

(21) Appl. No.: 18/788,530

(22) Filed: Jul. 30, 2024

(30) Foreign Application Priority Data
Aug. 4, 2023 (JP) 2023-127912
Oct. 13, 2023 (JP) 2023-177378

(51) Int. Cl. H01J 37/32

(52) U.S. Cl. CPC H01J 37/32449; H01J 37/3211; H01J 37/32119; H01J 2237/3341

(57) ABSTRACT

A method of etching a copper layer formed on a substrate arranged inside a processing chamber of a substrate processing apparatus, includes: a first operation of supplying a first processing gas that contains at least a first chlorine-containing gas and does not contain a hydrogen gas into the processing chamber, and generating a first product from the copper layer by a first plasma generated from the first processing gas; and a second operation of supplying a second processing gas that contains at least the hydrogen gas and does not contain the first chlorine-containing gas and a second chlorine-containing gas into the processing chamber, and generating a second product from the first product by a second plasma generated from the second processing gas. The first operation and the second operation are alternately executed in a repetitive manner a predetermined number of times.

### CROSS-REFERENCE TO RELATED APPLICATIONS

This application is based upon and claims the benefit of priority from Japanese Patent Application Nos. 2023-127912 and 2023-177378, filed on Aug. 4, 2023, and Oct. 13, 2023, respectively, the entire contents of which are incorporated herein by references.

### TECHNICAL FIELD

The present disclosure relates to a copper-layer etching method and a substrate processing apparatus.

### BACKGROUND

Along with an increase in size and resolution of display devices, copper (Cu) is used as a low-resistance wiring material in a display element. Wet etching is usually used to form copper wiring. A copper layer on a substrate is etched to follow a predetermined pattern. However, with recent miniaturization and higher density, it may be difficult to control a shape in a wet process. Therefore, accurate patterning using dry etching is required.

In the related art, a copper dry etching method uses chlorine plasma generated from chlorine (Cl)-based gas. In this etching method, copper chloride is generated as a reaction product from copper and the chlorine plasma, and the copper is etched by vaporizing the copper chloride. Since the generated copper chloride has a low vapor pressure, heating using a lamp or the like is required for vaporization (for example, see Patent Document 1).

On the other hand, an organic light emitting diode (OLED) as a display element used in recent display devices has a light emitting layer formed of an organic material. Therefore, there is a need for a copper-layer etching method that does not require heating in a display element manufacturing process. As such an etching method, a method is known using a processing gas containing a hydrogen chloride (HCl) gas and a hydrogen (H₂) gas to generate chlorine radicals and hydrogen radicals from the processing gas in an electron cyclotron resonance (ECR)-type plasma processing apparatus. In this etching method, copper(II) chloride (CuCl₂) is generated from the copper layer by the chlorine radicals, and a trimer (Cu₃Cl₃) of copper(I) chloride (CuCl) is generated from the copper(II) chloride by the hydrogen radicals. Since the trimer of the copper (I) chloride has a high vapor pressure, the trimer of the copper (I) chloride vaporizes almost simultaneously with generation thereof. Thus, the copper layer may be etched without the heating (for example, see Patent Document 2).

### PRIOR ART DOCUMENT

### Patent Document

Patent Document 1: Japanese Laid-Open Patent Publication No. H01-160035
Patent Document 1: U.S. Laid-Open Patent Publication No. 2019/0103287

### SUMMARY

According to one aspect of the present disclosure, a method of etching a copper layer formed on a substrate arranged inside a processing chamber of a substrate processing apparatus, includes: a first operation of supplying a first processing gas that contains at least a first chlorine-containing gas and does not contain a hydrogen gas into the processing chamber, and generating a first product from the copper layer by a first plasma generated from the first processing gas; and a second operation of supplying a second processing gas that contains at least the hydrogen gas and does not contain the first chlorine-containing gas and a second chlorine-containing gas into the processing chamber, and generating a second product from the first product by a second plasma generated from the second processing gas, wherein the first operation and the second operation are alternately executed in a repetitive manner a predetermined number of times.

### BRIEF DESCRIPTION OF DRAWINGS

The accompanying drawings, which are incorporated in and constitute a portion of the specification, illustrate embodiments of the present disclosure, and together with the general description given above and the detailed description of the embodiments given below, serve to explain the principles of the present disclosure.

FIG. 1 is a cross-sectional view schematically illustrating a configuration of a substrate processing apparatus according to an embodiment of a technique of the present disclosure.

FIG. 2 is a diagram illustrating a metal window provided in the substrate processing apparatus of FIG. 1 when viewed from a side of a processing space.

FIGS. 3A to 3E are process diagrams for explaining reactions used in a copper-layer etching method according to an embodiment of the technique of the present disclosure.

FIG. 4 is a flowchart illustrating the copper-layer etching method according to the embodiment of the technique of the present disclosure.

FIGS. 5A to 5C are enlarged partial cross-sectional views schematically illustrating partial SEM images of a cross-section of a test piece according to Comparative Example and Example.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In a technique disclosed in Patent Document 2 described above, when the generated copper (II) chloride is vaporized by heat, the copper(II) chloride re-solidifies and deposits in a low-temperature area inside a processing chamber, thereby causing occurrence of particles. For this reason, an increase in temperature of the copper(II) chloride is suppressed by utilizing heat absorption when the trimer of the copper(I) chloride is generated, thereby suppressing the vaporization of the copper(II) chloride. Therefore, it is necessary to simultaneously generate the copper(II) chloride and the trimer of the copper(I) chloride. For this purpose, the chlorine radicals used to generate the copper(II) chloride and the hydrogen radicals used to generate the trimer of the copper (I) chloride are simultaneously present inside the processing chamber of the ECR-type plasma processing apparatus. As a result, a hydrogen chloride gas, which is a source of the chlorine radicals, is present inside the processing chamber while etching the copper layer.

However, the hydrogen chloride gas corrodes a hard mask used as an etching mask. Therefore, when the hydrogen chloride gas exists inside the processing chamber for a long period of time, the shape of the hard mask will collapse due to the hydrogen chloride gas. As a result, shape controllability is deteriorated when forming a desired shape on the copper layer.

In addition, since the copper(II) chloride and the trimer of the copper(I) chloride are simultaneously generated, it is difficult to achieve compatibility of optimization of conditions for generating the copper(II) chloride and conditions for generating the trimer of the copper(I) chloride. Therefore, promotion of the generation of the copper(II) chloride and promotion of the generation of the trimer of the copper(I) chloride are not compatible. As a result, an etch rate of the copper layer decreases, which may increase an etching execution time required to form a desired shape on the copper layer. For example, the etching execution time may be 120 seconds to 300 seconds.

In contrast, a technique according to the present disclosure suppresses a decrease in shape controllability when forming the desired shape on the copper layer and also suppresses a decrease in the etch rate of the copper layer.

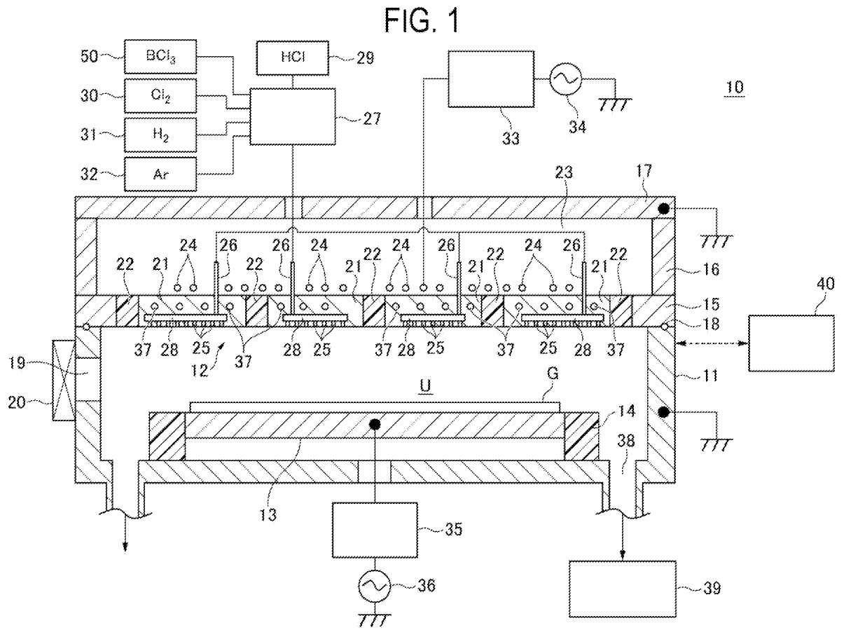

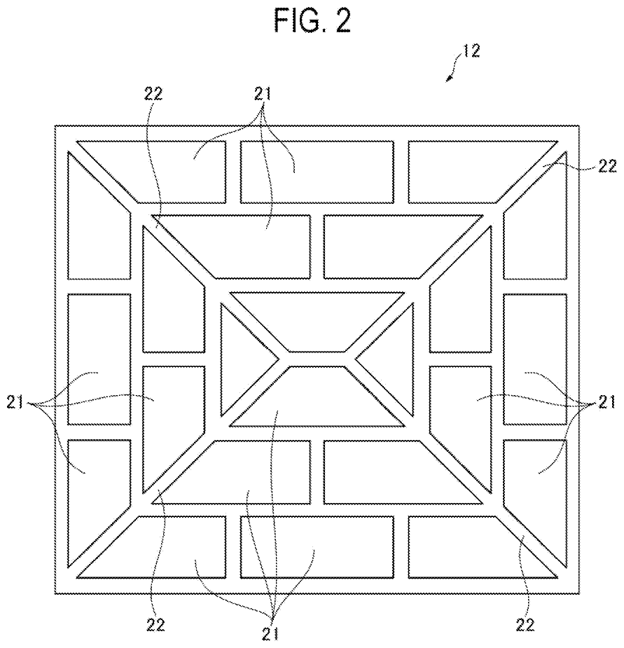

Hereinafter, embodiments of the technique of the present disclosure will be described with reference to the drawings. FIG. 1 is a cross-sectional view schematically illustrating a configuration of a substrate processing apparatus according to the embodiment, and FIG. 2 is a diagram illustrating a metal window provided in a substrate processing apparatus 10 of FIG. 1 when viewed from a side of a processing space.

The substrate processing apparatus 10 of FIG. 1 is an inductively coupled plasma processing apparatus. The substrate processing apparatus 10 etches a thin copper layer formed on a surface of a rectangular substrate, for example, a glass substrate G for flat panel display (FPD) (hereinafter referred to as a “substrate G”), using high-density plasma generated from a processing gas.

The substrate processing apparatus 10 includes a tubular processing chamber 11 made of a conductive material, for example, aluminum or an alloy containing aluminum. The processing chamber 11 accommodates the substrate G and is electrically grounded. An upper portion of the processing chamber 11 is hermetically closed by a metal window 12. A stage 13 on which the substrate G is placed is arranged in a lower portion of the interior of the processing chamber 11. The stage 13 faces the metal window 12. In the processing chamber 11, a processing space U is formed between the stage 13 and the metal window 12. In the processing space U, high-density plasma is generated from the processing gas, as will be described later.

An electrostatic chuck, which is not shown, is provided on an upper surface of the stage 13, and the substrate G placed on the stage 13 is attracted to and held on the stage 13 by the electrostatic chuck. Further, in order to control a temperature of the substrate G placed on the stage 13 by controlling a temperature of the stage 13, a temperature control mechanism, for example, a chiller using a refrigerant or a heat-transfer-gas supply mechanism (both not shown), is provided inside the stage 13. The stage 13 is installed on a bottom surface of the processing chamber 11 via an insulator frame 14.

A metal frame 15 is provided at an upper end of a sidewall of the processing chamber 11. A sidewall portion 16 is provided on an upper surface of the metal frame 15. The sidewall portion 16 supports a ceiling plate 17 and is electrically grounded. The ceiling plate 17 covers the metal window 12 from above. A seal member 18 such as an O-ring is provided between the sidewall of the processing chamber 11 and the metal frame 15 to keep the processing space U airtight. Further, a loading/unloading port 19 for loading and unloading the substrate G into/from the processing space U, and a gate valve 20 for opening/closing the loading/unloading port 19 are provided in the sidewall of the processing chamber 11.

As shown in FIG. 2, the metal window 12 has a rectangular shape and is divided into a plurality of divided pieces 21. In this embodiment, while the metal window 12 is divided into 24 divided pieces 21, the number of the divided pieces 21 is not limited to 24 and may be changed depending on the size of the metal window 12 or controllability of plasma distribution. Each divided piece 21 is made of, for example, a non-magnetic and conductive metal, aluminum, or an alloy containing aluminum. In the metal window 12, a partition member 22 made of an insulator is arranged between the divided pieces 21 adjacent to each other. The partition member 22 partitions the adjacent divided pieces 21 so as to be electrically insulated from each other. Considering that an area between the processing space U and an antenna room 23 which will be described later is kept airtight with the metal window 12 disposed therebetween, it is desirable that the partition member 22 is formed in one piece.

Referring back to FIG. 1, in the substrate processing apparatus 10, a space surrounded by the metal window 12, the sidewall portion 16, and the ceiling plate 17 constitutes the antenna room 23. An inductively coupled antenna 24 is arranged in the antenna room 23 so as to face the substrate G placed on the stage 13 via the metal window 12. The inductively coupled antenna 24 is arranged to be spaced apart from the metal window 12 via a spacer made of, for example, an insulator, which is not shown.

The inductively coupled antenna 24 is constituted by a plurality of antenna segments. Each antenna segment is arranged in a circumferential direction of the metal window 12 to constitute an annular antenna as a whole. Further, since the antenna segments are arranged on the same plane, the inductively coupled antenna 24 has a flat antenna shape. Depending on processing content, the antenna segments may be arranged across the divided pieces 21 or may be arranged so as to be within a projection range of the divided pieces 21 without being distributed across the divided pieces 21. Further, the inductively coupled antenna 24 may be constituted with one antenna wire or a plurality of antenna wires bundled together. In this case, the inductively coupled antenna 24 is distributed in a region facing the divided pieces 21 and is spirally arranged in the circumferential direction of the metal window 12. Further, a plurality of inductively coupled antennas 24 may be concentrically arranged.

As shown in FIG. 1, a plurality of gas holes 25 which is open toward the processing space U is formed in each divided piece 21. A gas supply pipe 26 is connected to each divided piece 21, and the gas supply pipe 26 is connected to a gas supply device 27. Further, a gas diffusion chamber 28 is formed inside each divided piece 21. The gas supply device 27 introduces the processing gas into the gas diffusion chamber 28 via the gas supply pipe 26. The processing gas introduced into the gas diffusion chamber 28 is supplied to the processing space U from each gas hole 25. Therefore, each divided piece 21 has a gas shower structure composed of the gas holes 25 and the gas diffusion chamber 28.

A hydrogen chloride gas source 29 that supplies a hydrogen chloride gas as a chlorine-containing gas, a chlorine gas source 30 that supplies a chlorine (Cl₂) gas as the chlorine-containing gas, and a boron trichloride gas source 50 that supplies a boron trichloride (BCl₃) gas as the chlorine-containing gas are connected to the gas supply device 27. In addition, as the chlorine-containing gas, only one or both of the hydrogen chloride gas, the chlorine gas, and the boron trichloride gas may be used, and thus, only one or two of the hydrogen chloride gas source 29, the chlorine gas source 30, and the boron trichloride gas source 50 may be connected to the gas supply device 27. Further, a hydrogen gas source 31 that supplies a hydrogen gas and an argon gas source 32 that supplies an argon (Ar) gas as a diluent gas are connected to the gas supply device 27. The diluent gas is not limited to the argon gas as long as the diluent gas has a function of diluting a supplied gas. The gas supply device 27 includes, therein, pipes connected to the gas sources 29, 30, 31, 32, and 50, respectively, gas flow rate control devices (not shown) disposed in the respective pipes, and valves (not shown). The pipes are connected downstream of the corresponding flow control devices and valves, so that the gases join in the gas supply device 27. The gas supply device 27 controls flow rates of gases flowing into the gas supply device 27 from the gas sources 29, 30, 31, 32, and 50 using the flow rate control devices based on instructions from a controller 40 (to be described later) and generates the processing gas by combining the gases. Instead of providing the gas supply device 27 for combining the gases, the flow rate control devices and the valves may be provided on the pipes connected to the gas sources 29, 30, 31, 32, and 50, and the pipes may be connected downstream of the flow rate control devices and the valves. Further, as the chlorine-containing gas, chlorine-containing gases other than the hydrogen chloride gas, the chlorine gas, and the boron trichloride gas may be used. Further, gas sources corresponding to other chlorine-containing gases may be connected to the gas supply device 27.

Further, in the substrate processing apparatus 10, a radio-frequency power source 34 is connected to the inductively coupled antenna 24 via a matcher 33. The radio-frequency power source 34 supplies a radio frequency power of, for example, 13.56 MHz for plasma generation to the inductively coupled antenna 24. As a result, an eddy current circulating from an upper surface (the inductively coupled antenna 24) to a lower surface (the processing space U) is induced in each of the divided pieces 21 constituting the metal window 12. An electromagnetic field is formed in the processing space U by the eddy current. Then, the electromagnetic field is applied to the processing gas supplied to the processing space U, so that the processing gas is excited and high-density plasma is generated from the processing gas.

In the substrate processing apparatus 10, a dielectric window made of a dielectric material may be used instead of the metal window 12. In this case, the electromagnetic field formed by the inductively coupled antenna 24 transmits through the dielectric window and is directly applied to the processing gas.

In addition, a radio-frequency power source 36 is connected to the stage 13 via a matcher 35. The radio-frequency power source 36 supplies a radio frequency power of, for example, 3.2 MHz, for bias to the stage 13. Thus, various ions in high-density plasma in the processing space U may be drawn into the substrate G so that the substrate G may be subjected to a variety of plasma processing.

In addition, in the substrate processing apparatus 10, each divided piece 21 is electrically insulated from other divided pieces 21 by the partition member 22, so that the eddy current is individually induced in each divided piece 21 of the metal window 12 and the electromagnetic field is individually generated in a region facing each divided piece 21. Therefore, by changing the size and arrangement of each divided piece 21, the distribution of the electromagnetic field generated in the processing space U may be controlled. As a result, a degree of plasma processing performed upon the substrate G (for example, an etch rate in etching processing) may be locally controlled.

In the substrate processing apparatus 10, a temperature control flow path 37 is formed inside each divided piece 21. A cooling medium or a heating medium is introduced into the temperature control flow path 37 to control the temperature of each divided piece 21. Since the degree of certain plasma processing also depends on temperature, the degree of plasma processing performed upon the substrate G may also be locally controlled by individually controlling the temperature of each divided piece 21.

Further, in the substrate processing apparatus 10, an exhaust port 38 is formed in the bottom surface of the processing chamber 11. An exhaust device 39 such as a turbomolecular pump or a dry pump is connected to the exhaust port 38. When performing a variety of plasma processing, the exhaust device 39 maintains the processing space U at a predetermined pressure lower than atmospheric pressure. Further, the substrate processing apparatus 10 is provided with the controller 40. The controller 40 includes a computer equipped with at least a CPU and a memory, and a recipe (program) for executing a variety of plasma processing including copper-layer etching processing (to be described later) is recorded in the memory.

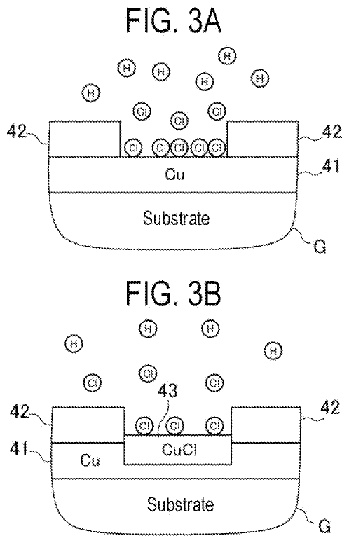

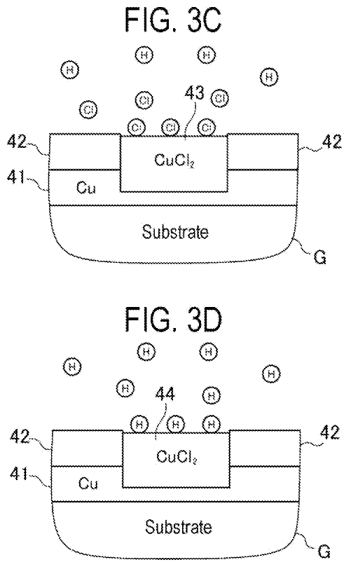

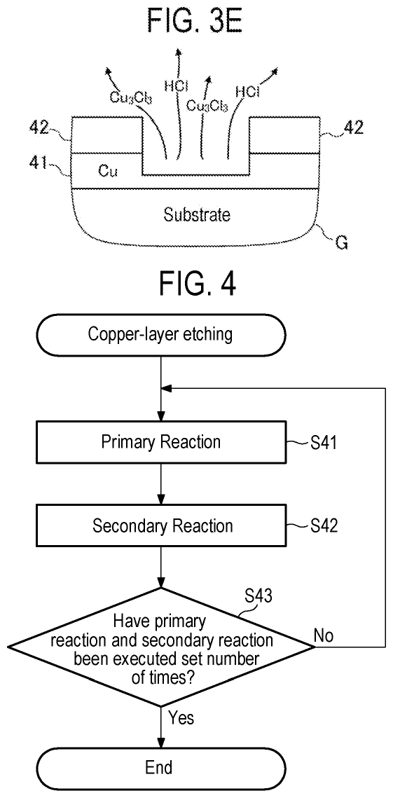

FIGS. 3A to 3E are process diagrams for explaining reactions used in the copper-layer etching method according to the embodiment. In FIGS. 3A to 3E, enlarged cross sections of a portion of the substrate G are illustrated. A thin copper layer 41 is formed on the surface of the substrate G, and a hard mask 42 is formed on the copper layer 41 with a pattern that exposes a portion of the copper layer 41. The hard mask 42 is made of, for example, a silicon oxide film.

The copper-layer etching method according to the embodiment is executed in the substrate processing apparatus 10.

In the copper-layer etching method according to the embodiment, as a primary reaction, copper(II) chloride (a first product) is first generated from a portion of the copper layer 41 (in a first operation). Specifically, an electromagnetic field is applied to a first processing gas containing a chlorine-containing gas to generate chlorine radicals (indicated by “Cl” in the figure) (first plasma), and the chlorine radicals react with the exposed copper layer 41 (FIG. 3A). In this case, first, a copper(I) chloride (CuCl) 43 is generated as a reaction product from the copper layer 41 (FIG. 3B). Thereafter, when the chlorine radicals are continuously generated from the first processing gas, additionally generated chlorine radicals react with the copper(I) chloride 43 to generate a copper(II) chloride (CuCl₂) 44 (FIG. 3C).

Chemical equations of when the copper(I) chloride and the copper(II) chloride are generated in this primary reaction are represented by the following equations (1) and (2).

Cu+Cl→CuCl (1)

CuCl+Cl→CuCl₂ (2)

The chlorine-containing gas of the first processing gas used in the primary reaction contains a hydrogen chloride gas alone, a chlorine gas alone, a boron trichloride gas alone, a mixed gas of the hydrogen chloride gas, the chlorine gas, and the boron trichloride gas, or a mixed gas of any two of the hydrogen chloride gas, the chlorine gas, and the boron trichloride gas. Further, while the first processing gas does not contain a hydrogen gas, the first processing gas may contain an argon gas in order to adjust a flow rate.

Next, as a secondary reaction, a trimer (Cu₃Cl₃) (a second product) of the copper(I) chloride is generated from the copper(II) chloride 44 (in a second operation). Specifically, hydrogen radicals (indicated by “H” in the figure) (second plasma) are generated by applying an electromagnetic field to a second processing gas containing the hydrogen gas and react with the copper(II) chloride 44 (FIG. 3D). In this case, the trimer of the copper(I) chloride and hydrogen chloride are produced from the copper(II) chloride 44. Since the trimer of the copper(I) chloride or the hydrogen chloride has a high vapor pressure, the trimer of the copper(I) chloride or the hydrogen chloride immediately vaporizes and then scatters. As a result, the exposed copper layer 41 is removed (etched) (FIG. 3E).

Chemical equations of when the trimer of the copper(I) chloride or the hydrogen chloride is generated in the secondary reaction are represented by the following equations (3) and (4).

3CuCl₂+3H→Cu₃Cl₃↑+3HCl↑ (3)

3CuCl₂+3/2H₂→Cu₃Cl₃↑+3HCl↑ (4)

The second processing gas used in the secondary reaction includes the hydrogen gas alone and does not contain the chlorine-containing gas, for example, the chlorine gas, the hydrogen chloride gas, or the boron trichloride gas. Further, the second processing gas contains neither the chlorine-containing gas contained in the first processing gas nor other chlorine-containing gases that are not included in the first processing gas. The other chlorine-containing gases may be a gas that is not included in the first processing gas among the chlorine gas, the hydrogen chloride gas, and the boron trichloride gas, or may be the chlorine-containing gas other than the chlorine gas, the hydrogen chloride gas, and the boron trichloride gas. However, the second processing gas may also contain the argon gas in order to adjust a flow rate.

FIG. 4 is a flowchart illustrating the copper-layer etching method according to the embodiment. This copper-layer etching method is executed by the controller 40 according to a predetermined recipe.

First, the controller 40 executes the primary reaction (step S41). In the primary reaction, first, the gas supply device 27 controls flow rates of gases flowing from the hydrogen chloride gas source 29, the chlorine gas source 30, the boron trichloride gas source 50, and the argon gas source 32 and mixes the gases to generate the first processing gas.

Subsequently, the first processing gas is supplied from the gas holes 25 of each divided piece 21 to the processing space U, and the radio-frequency power for plasma generation is supplied from the radio-frequency power source 34 to the inductively coupled antenna 24. In this case, an electromagnetic field formed in the processing space U is applied to the first processing gas to generate chlorine radicals. These chlorine radicals react with the exposed copper layer 41 that is not covered by the hard mask 42 on the substrate G to generate the copper(I) chloride 43 from the copper layer 41. Then, the chlorine radicals are continuously generated and the copper chloride(II) 44 is generated from the copper chloride 43 by additionally generated chlorine radicals.

Thereafter, the supply of the first processing gas to the processing space U is stopped to stop the generation of the chlorine radicals, and the transformation of the copper layer 41 into the copper(II) chloride 44 is stopped, thereby terminating the primary reaction. In this case, a duration from the start of the supply of the first processing gas to the processing space U to the stop of the supply is set to be shorter than a time required for all of the exposed copper layer 41 to transform into the copper(II) chloride 44. The duration from the start of the supply of the first processing gas to the stop of the supply may be set based on the results of prior experiments or determined in real time by observing plasma emission intensity or the like.

In the primary reaction, the substrate G is heated by heat input from the plasma and reaction heat. As a result, a portion of the copper chloride(I) or the copper chloride(II) may be vaporized. Therefore, in this embodiment, the vaporization of the copper (I) chloride and the copper (II) chloride is suppressed by cooling the substrate G in the primary reaction. Specifically, the temperature of the substrate G is maintained at 50 degrees C. or lower using a chiller of the stage 13. In this case, a set temperature of a refrigerant of the chiller is set to −40 degrees C. or lower.

Subsequently, the controller 40 executes the secondary reaction (step S42). In the secondary reaction, the gas supply device 27 first controls the flow rates of gases flowing from the hydrogen gas source 31 and the argon gas source 32, and mixes the gases to generate a second processing gas.

Thereafter, the second processing gas is supplied to the processing space U from the gas holes 25 of each divided piece 21. In this case, the electromagnetic field formed in the processing space U is applied to the second processing gas to generate hydrogen radicals. The hydrogen radicals react with the copper(II) chloride 44 to generate a trimer of the copper(I) chloride and hydrogen chloride from the copper(II) chloride 44. When the trimer of the copper(I) chloride and the hydrogen chloride are generated, the trimer of the copper(I) chloride and the hydrogen chloride immediately vaporize and scatter. As a result, the copper(II) chloride 44 that has been generated in the primary reaction is removed, and the copper layer 41 that has unreacted in the primary reaction is newly exposed.

Thereafter, the supply of the second processing gas to the processing space U is stopped to stop the generation of the hydrogen radicals. In this case, a duration from the start of the supply of the second processing gas to the processing space U to the stop of the supply may be set to be longer than a time period during which the copper(II) chloride 44 generated in the primary reaction is completely removed. The duration from the start of the supply of the second processing gas to the stop of the supply is also set based on the results of prior experiments, or determined in real time by observing plasma emission intensity or the like.

However, even in an environment in which the hydrogen radicals exist, the substrate G is heated due to the plasma heat input and the reaction heat, so that a portion of the copper chloride (I) or the copper chloride (II) may be vaporized. Therefore, even in the secondary reaction, the substrate G is cooled. Specifically, even in the secondary reaction, the temperature of the substrate G is maintained at 50 degrees C. or lower using the chiller of the stage 13. In this case, the temperature of the refrigerant of the chiller is set to −40 degrees C. or lower.

Next, it is determined whether the primary reaction and the secondary reaction have been alternately executed in a repetitive manner a set number of times (predetermined number of times) or more (step S43). When the primary reaction and the secondary reaction are alternately executed in a repetitive manner the set number of times or more, the etching method is terminated. When the primary reaction and the secondary reaction have not been alternately executed in a repetitive manner the set number of times or more, the etching method returns to step S41. The set number of times in step S43 is set to be greater than the number of repetitions of the primary reaction and the secondary reaction required to completely remove the exposed copper layer 41. This set number of times is set based on the results of prior experiments or the like.

According to the embodiment, in order to etch the exposed copper layer 41, the primary reaction using the first processing gas containing a chlorine-containing gas and the secondary reaction using the second processing gas that contains a hydrogen gas but does not contain a hydrogen chloride gas are repeatedly executed. That is, when etching the copper layer 41, there is a duration in which the hydrogen chloride gas is not present in the processing space U of the processing chamber 11 (a duration in which the secondary reaction is executed), and there is no case in which the hydrogen chloride gas is present for a long period of time in the processing space U. This prevents the hard mask from collapsing due to the hydrogen chloride gas and suppresses deterioration in a desired shape on the copper layer, i.e., shape controllability when forming, for example, a trench or a taper.

Further, in the embodiment, the primary reaction and the secondary reaction are not executed simultaneously and are performed separately. Thus, while optimizing conditions for generating the copper(II) chloride in the primary reaction, it is possible to optimize conditions for generating the trimer of the copper(I) chloride in the secondary reaction. As a result, it is possible to achieve compatibility of promotion of the generation of the copper(II) chloride and promotion of the generation of the trimer of the copper(I) chloride, thereby suppressing a decrease in the etch rate of the exposed copper layer 41.

Further, in the embodiment, the substrate processing apparatus 10, which is an inductively coupled plasma processing apparatus rather than an ECR-type plasma processing apparatus, is used. Although the ECR-type plasma processing apparatus is capable of generating high-density plasma, it is difficult to constantly maintain a resonance region between microwaves and magnetic fields over a large area, and thus it is difficult to generate high-density plasma from the processing gases over a wide range. Therefore, in order to perform the plasma processing on the substrate G used in a large display device using the ECR-type plasma processing apparatus, a scanning mechanism for scanning the surface of the substrate G from a plasma generation source is required and thus it is inevitable that the plasma processing apparatus will become larger and more complex.

On the other hand, as mentioned above, since the inductively coupled plasma processing apparatus uses the flat antenna to form plasma uniformly over a large area, high-density plasma may be generated from the processing gases over a wide range. This makes it possible to eliminate the need for the scanning mechanism such as the ECR-type plasma processing apparatus even when performing plasma processing on the substrate G used in the large display device. Therefore, in the embodiment, it is possible to avoid increase of the size and complexity of the substrate processing apparatus 10.

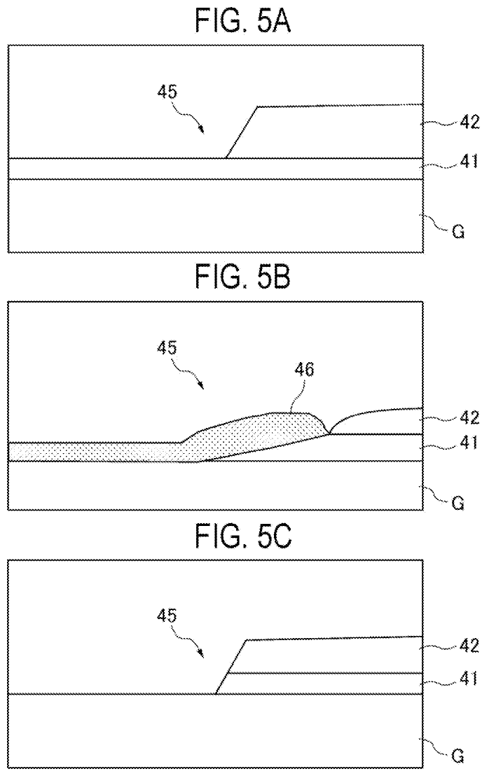

Next, the results of experiments will now be described. First, the present applicant prepared a test piece 45 (see FIG. 5A) in which the copper layer 41 having a film thickness of 5000 Å is formed on the surface of the substrate G, and the hard mask 42 exposing a portion of the copper layer 41 is formed on the copper layer 41. FIGS. 5A to 5C are enlarged partial cross-sectional views schematically illustrating partial SEM images of the cross-section of the test piece 45.

Here, even if a processing gas uses only a hydrogen chloride gas, when the processing gas is excited, a certain amount of hydrogen radicals is generated along with chlorine radicals. As a result, copper is etched even though an etch rate is low. Therefore, as Comparative Example for comparing the degree of consumption of the hard mask 42, the present applicant continued to supply the processing gas that contains the hydrogen chloride gas but does not contain a hydrogen gas to the processing space U in the substrate processing apparatus 10, thereby etching the copper layer 41 of the test piece 45. That is, the copper layer 41 was etched only by a processing step using the hydrogen chloride gas without performing a processing step using the hydrogen gas.

In Comparative Example, as processing conditions, the pressure of the processing space U was set to 1 mTorr, the output (source power) of a radio-frequency power for plasma generation was set to 4 kW, and the output (bias power) of a radio-frequency power for bias was set to 4 kW. Further, the flow rate of the hydrogen chloride gas was set to 36 sccm, and the set temperature of the refrigerant of the chiller of the stage 13 was set to −40 degrees C. or lower in order to maintain the temperature of the substrate G at 50 degrees C. or lower. Further, the processing gas was continuously supplied to the processing space U for 300 seconds. That is, the copper layer 41 was etched only by the processing step using the hydrogen chloride for 300 seconds.

In addition, as Example of the present embodiment, the present applicant etched the copper layer 41 of the test piece 45 by executing the copper-layer etching method illustrated in FIG. 4 using the substrate processing apparatus 10.

The processing conditions of Example are basically the same as the processing conditions of Comparative Example. The output of the source power and the output of the bias power were each set to 4 kW as in Comparative Example, but the processing conditions of Example were different from the processing conditions of Comparative Example in that the processing step (primary reaction) using the hydrogen chloride and the processing step using the hydrogen (secondary reaction) were alternately executed. In the primary reaction, a hydrogen chloride gas alone was used as the chlorine-containing gas of the first processing gas, and a flow rate thereof was set to 36 sccm. Further, in the secondary reaction, the flow rate of the hydrogen gas of the second processing gas was set to 150 sccm. Then, the primary reaction and the secondary reaction were alternately executed in a repetitive manner a predetermined number of times for 300 seconds.

In Comparative Example, as shown in FIG. 5B, although the copper layer 41 has been etched, the shape of the hard mask 42 collapsed, and as a result, the shape of the remaining portion of the copper layer 41 did not reflect the shape of the hard mask 42 (see FIG. 5A) before etching. This is presumably because, in Comparative Example, the processing gas containing the hydrogen chloride gas was continuously supplied to the processing space U, so that the hard mask 42 was eroded by the hydrogen chloride gas for a long period of time. Further, as a result of the shape of the hard mask 42 collapsed, the copper layer 41 in portions that should originally be covered by the hard mask 42 was chlorinated and swollen, and remained as a swollen layer 46.

In contrast, in this Example, as shown in FIG. 5C, the copper layer 41 is etched while the hard mask 42 maintains the shape thereof, and the shape of the remaining portion of the copper layer 41 also reflected the shape of the hard mask 42 before etching. This is presumably because, in this Example, the primary reaction and the secondary reaction were alternatively executed in a repetitive manner, so that the hydrogen chloride gas did not exist in the processing space U for a long period of time, and the hard mask 42 was not eroded by the hydrogen chloride gas.

Further, the etch rate of the hard mask 42 in Comparative Example was 2.2 or more times the etch rate in this Example. This result also confirmed that the hard mask 42 was eroded by the hydrogen chloride gas in Comparative Example, while the hard mask 42 was not eroded by the hydrogen chloride gas in this Example.

As described above, it was confirmed that, according to the copper-layer etching method according to the present embodiment, the primary reaction and secondary reaction are alternately executed in a repetitive manner so that the shape of the hard mask 42 is prevented from collapsing and a decrease in shape controllability when forming a desired shape on the copper layer shape is suppressed.

Further, although the processing conditions were almost the same in Comparative Example and this Example, the etch rate of the copper layer 41 in Comparative Example was 0.5 times the etch rate of the copper layer 41 in this Example. The reason for this was that in Comparative Example, since the hydrogen chloride gas alone was used, chlorine radicals were present in a larger amount than hydrogen radicals. In other words, this is believed to be due to a higher ratio of the chlorine radicals to the hydrogen radicals. Specifically, when the chlorine radicals exist in large amounts relative to the hydrogen radicals, the chlorine radicals hindered the hydrogen radicals from contacting the copper (II) chloride 44, and there was a lack of the hydrogen radicals for converting the copper (II) chloride 44 into the trimer of the copper(I) chloride. This is because, as a result of the hinderance of this contact and the lack of the hydrogen radicals, the generation of the trimer of the copper(I) chloride from the copper(II) chloride 44 was suppressed.

However, if deposition occurs inside the processing chamber 11, the deposition leads to issues such as formation of particles, so the occurrence of deposition should be suppressed as much as possible. For example, in the primary reaction, even when the hydrogen chloride gas is used as the chlorine-containing gas, the generation of deposition may be suppressed by lowering the output of a bias power. At this time, the etch rate may also decrease. However, the present applicant has found that, when the boron trichloride gas is used as the chlorine-containing gas, it is possible to suppress the generation of deposition while maintaining a high etch rate compared to the case in which the hydrogen chloride gas is used.

The present applicant first etched the copper layer by executing the copper-layer etching method illustrated in FIG. 4 under conditions, as standard HCl conditions, that the hydrogen chloride gas is used, both the output of the source power and the output of the bias power output are set to 4 kW, and a gas flow rate is set to 36 sccm. A deposition ratio obtained by dividing the amount of deposition generated in this case by the amount of etching of the copper layer is defined as a standard deposition ratio, and an etch rate in this case is defined as a standard etch rate. The number of repetitions of the primary reaction and the secondary reaction under the standard HCl conditions was 5 times, and a set temperature of the chiller of the stage 13 was −40 degrees C.

Subsequently, the present applicant etched the copper layer by setting the output of the source power to 6 kW, the output of the bias power to 0 kW, and the number of repetitions of the primary reaction and the secondary reaction to 9 times as low-bias HCl conditions and setting the other conditions to be same as the standard HCl conditions. Even under the low-bias HCl conditions, the deposition ratio obtained by dividing the amount of generated deposition by the amount of etching of the copper layer and the etch rate were obtained. As a result, it was found that, under the low-bias HCl conditions, the deposition ratio was improved to be low by 25% compared to the standard deposition ratio, but the etch rate was also significantly lowered by 52% compared to the standard etch rate.

Under the low-bias HCl conditions, both the output of the source power and the number of repetitions of the primary reaction and the secondary reaction are increased compared to those under the standard HCl conditions. Thus, it is expected that there will be an increase in the amount of deposition and the etch rate. However, contrary to expectations, the reason why both the amount of deposition and the etch rate under the low-bias HCl conditions are reduced is considered to be that the effect of setting the bias power to 0 kW was significant.

On the other hand, since the etch rate under the low-bias HCl conditions was lowered by almost half the etch rate under the standard HCl conditions, it was necessary to improve the etch rate. Therefore, the present applicant etched the copper layer under low-bias BCl₃ conditions in which the boron trichloride gas is used as the chlorine-containing gas while keeping the other conditions the same as the low-bias HCl conditions. Even under the low-bias BCl₃ conditions, the deposition ratio obtained by dividing the amount of generated deposition by the amount of etching of the copper layer and the etch rate were acquired. As a result, it was confirmed that, under the low-bias BCl₃ conditions, the deposition ratio was 25% lower than the standard deposition ratio, which is equivalent to the deposition ratio under the low-bias HCl conditions, and the etch rate increased by 72% compared to that under the low-bias HCl conditions. In other words, under the low-bias BCl₃ conditions, the deposition ratio was the same as that under the low-bias HCl conditions, and the etch rate of the copper layer was lower than that under the standard HCl conditions but was more than 70% higher than that under the low-bias HCl conditions.

As described above, it was found that the use of the boron trichloride gas as the chlorine-containing gas has the effect of suppressing the occurrence of deposition while suppressing a decrease in the etch rate.

In the embodiment, while the case in which the first operation is first performed, the second operation is then performed, and then the first operation and the second operation are repeated to etch the copper layer has been described, a third operation may be additionally performed before the first operation. The third operation is an operation performed under the same processing conditions as the second operation by supplying the second processing gas. That is, in this case, after performing the third operation and processing the substrate using the hydrogen gas, the first operation is performed, the second operation is performed, and then the first operation and the second operation are repeated. In this way, by performing the third operation first, the surface of the copper layer is modified by hydrogen, which has the effect of promoting the primary reaction or the secondary reaction.

According to the present disclosure in some embodiments, it is possible to suppress a decrease in the etch rate of the copper layer while suppressing a decrease in shape controllability upon forming a desired shape on the copper layer.

While the method of etching the copper layer as an exemplary embodiment of the present disclosure has been described above, the present disclosure is not limited to the above embodiment, but various modifications and changes may be made without departing from the spirit of the disclosures.

What is claimed is:

1. A method of etching a copper layer formed on a substrate arranged inside a processing chamber of a substrate processing apparatus, the method comprising:
a first operation of supplying a first processing gas that contains at least a first chlorine-containing gas and does not contain a hydrogen gas into the processing chamber, and generating a first product from the copper layer by a first plasma generated from the first processing gas; and
a second operation of supplying a second processing gas that contains at least the hydrogen gas and does not contain the first chlorine-containing gas and a second chlorine-containing gas into the processing chamber, and generating a second product from the first product by a second plasma generated from the second processing gas,
wherein the first operation and the second operation are alternately executed in a repetitive manner a predetermined number of times.

2. The method of claim 1, wherein the first chlorine-containing gas is a hydrogen chloride gas alone, a chlorine gas alone, a boron trichloride gas alone, a mixed gas of the hydrogen chloride gas, the chlorine gas, and the boron trichloride gas, or a mixed gas of two gases among the hydrogen chloride gas, the chlorine gas, and the boron trichloride gas.

3. The method of claim 1, wherein a temperature of the substrate is maintained at 50 degrees C. or lower in the first operation and the second operation.

4. The method of claim 1, wherein the substrate processing apparatus includes a stage on which the substrate is placed, a metal window provided to face the stage and composed of a plurality of divided pieces, and an inductively coupled antenna provided to face the stage via the metal window and composed of a plurality of antenna segments,
wherein, in the first operation, the first plasma is generated by applying, to the first processing gas, an electromagnetic field from the inductively coupled antenna via the metal window, and
wherein, in the second operation, the second plasma is generated by applying, to the second processing gas, the electromagnetic field from the inductively coupled antenna via the metal window.

5. The method of claim 1, further comprising: a third operation of processing the substrate by the second plasm generated from the second processing gas by supplying the second processing gas into the processing chamber before executing the first operation.

6. A substrate processing apparatus for etching a copper layer formed on a substrate, the substrate processing apparatus comprising:
a stage configured to place the substrate thereon;
a processing chamber provided with the stage therein;
a metal window provided to face the stage and composed of a plurality of divided pieces;
an inductively coupled antenna provided to face the stage via the metal window and composed of a plurality of antenna segments; and
a controller,
wherein the controller executes a copper-layer etching method including a first operation of supplying a first processing gas that contains at least a first chlorine-containing gas and does not contain a hydrogen gas into the processing chamber, and generating a first product from the copper layer by a first plasma generated from the first processing gas, and a second operation of supplying a second processing gas that contains at least the hydrogen gas and does not contain the first chlorine-containing gas and a second chlorine-containing gases into the processing chamber, and generating a second product from the first product by a second plasma generated from the second processing gas, and
wherein, in the copper-layer etching method, the first operation and the second operation are alternately executed in a repetitive manner a predetermined number of times.
